(19) United States
(12) Patent Application Publication
(10) Pub. No.: US 2026/0001971 A1
(43) Pub. Date: Jan. 1, 2026

(54) CURABLE COMPOSITION, CURED LAYER USING THE COMPOSITION AND DISPLAY DEVICE INCLUDING THE CURED LAYER

(71) Applicant: SAMSUNG SDI CO., LTD., Yongin-si (KR)

(72) Inventors: Sohyun KIM, Suwon-si (KR); Yonghee KANG, Suwon-si (KR); Chul-Kyu KIM, Suwon-si (KR); Jihyeon YIM, Suwon-si (KR); Bumjin LEE, Suwon-si (KR)

(21) Appl. No.: 19/235,411

(22) Filed: Jun. 11, 2025

(30) Foreign Application Priority Data
Jun. 26, 2024 (KR) 10-2024-0083882

(51) Int. Cl. C08F 2/50; G03F 7/004; G03F 7/028; H10K 50/115

(52) U.S. Cl. CPC C08F 2/50; G03F 7/0043; G03F 7/028; H10K 50/115

(57) ABSTRACT

Provided are a curable composition, a cured layer produced using the curable composition, and a display device including the cured layer, the curable composition including (A) a quantum dot including a functional group represented by Chemical Formula 1; and (B) a polymerizable compound. In Chemical Formula 1, each substituent is the same as defined in the detailed description.

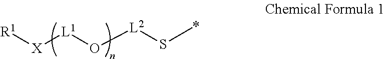

### CROSS-REFERENCE TO RELATED APPLICATION

The present application claims priority to and the benefit of Korean Patent Application No. 10-2024-0083882, filed on Jun. 26, 2024, in the Korean Intellectual Property, the entire content of which is hereby incorporated by reference.

### BACKGROUND

### 1. Field

Embodiments of this disclosure relate to a curable composition, a cured layer using the composition, a display device including the cured layer.

### 2. Description of the Related Art

With respect to general quantum dots, due to surface characteristics having hydrophobicity, a solvent in which it is dispersed is limited, and thus, it is difficult to introduce into a polar system such as a binder or a curable monomer.

For example, even for a quantum dot ink composition being actively researched, a polarity is relatively low in an initial step and it may be dispersed in a solvent used in a curable composition having a high hydrophobicity. Therefore, because 20 wt % or more of quantum dots are difficult to be included based on a total amount of the composition, it is difficult or impossible to increase light efficiency of the ink over a set or certain level. Even though the quantum dots are additionally added and dispersed in order to increase light efficiency, a viscosity exceeds a range capable of ink-jetting and thus processability may not be satisfied.

In order to achieve the viscosity range capable of ink-jetting, a method of lowering an ink solid content by dissolving about 50 wt % or more of a solvent based on a total amount of the composition, which also provides a somewhat satisfactory result in terms of viscosity. However, it may be considered to be a satisfactory result in terms of a viscosity, but nozzle drying due to solvent volatilization and nozzle clogging during ink-jetting, and reduction of a single film thickness as time passed after ink-jetting may become worse and it is difficult to control a thickness deviation after curing. Thus, it is difficult to apply the foregoing to actual processes.

Accordingly, a solvent-free curable composition (quantum dot ink composition) that does not use a solvent has been developed. However, due to an excessive amount of a polymerizable compound, problems arise, such as clogging and poor ejection due to nozzle drying caused by volatility, and a decrease in single film thickness due to volatilization of the jetted ink composition within the pattern partition wall pixel. Above all, the biggest problem is that it is difficult to improve the optical properties of the solvent-free curable composition.

The reality is that neither solvent-type curable composition nor solvent-free curable composition have yet demonstrated a satisfactory level of light resistance reliability.

### SUMMARY

Some example embodiments provide a curable composition having high stability of quantum dots, excellent dispersibility of quantum dots, and thus excellent reliability and optical properties such as heat resistance and light resistance.

Some example embodiments provide a cured layer produced using the curable composition.

Some example embodiments provide a display device including the cured layer.

Some example embodiments provide a curable composition including (A) a quantum dot including a functional group represented by Chemical Formula 1; and (B) a polymerizable compound.

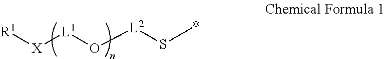

In Chemical Formula 1,
X is a sulfur atom or an oxygen atom,
R¹ is a monovalent functional group including a reactive group and a C3 to C20 cycloalkane ring,
L¹ and L² are each independently a substituted or unsubstituted C1 to C20 alkylene group, and
n is an integer between 2 and 10.

The reactive group may include a carbon-carbon double bond, an epoxy group, or a combination thereof.

R¹ may be represented by any one selected from Chemical Formulas R-1 to R-3.

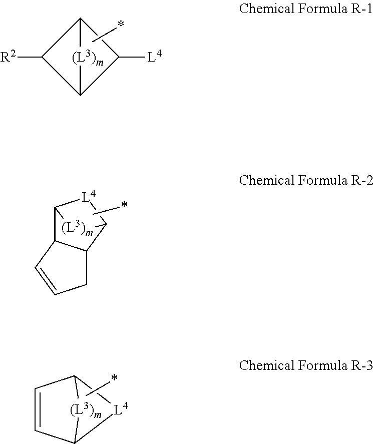

In Chemical Formulas R-1 to R-3,
R² is a ‘substituted or unsubstituted vinyl group’, a ‘substituted or unsubstituted epoxy group’, or a ‘C1 to C20 alkyl group substituted with an epoxy group and/or a vinyl group,’
L³ and L⁴ are each independently a substituted or unsubstituted C1 to C10 alkylene group, and
m is an integer of 0 or 1.

The functional group represented by Chemical Formula 1 may be represented by any one selected from Chemical Formula 1-1 to Chemical Formula 1-4.

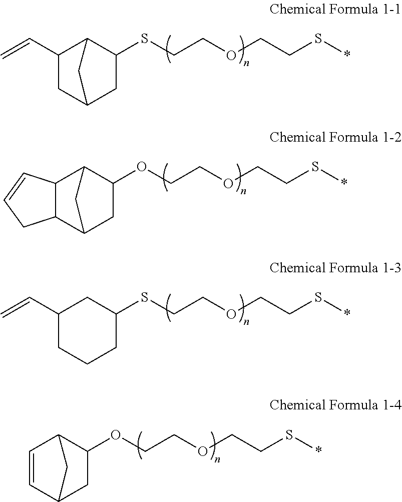

In Chemical Formula 1-1 to Chemical Formula 1-4,
n is an integer between 2 and 10.

The functional group represented by Chemical Formula 1 may be derived from a compound represented by Chemical Formula 2.

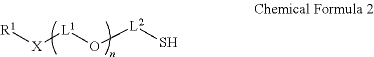

In Chemical Formula 2,
X is a sulfur atom or an oxygen atom,
R¹ is a monovalent functional group including a reactive group and a C3 to C20 cycloalkane ring,
L¹ and L² are each independently a substituted or unsubstituted C1 to C20 alkylene group, and
n is an integer between 2 and 10.

In Chemical Formula 2, the definitions of the reactive groups, X, R¹, L¹, L², and n are as described above.

The compound represented by Chemical Formula 2 may be represented by any one selected from Chemical Formula 2-1 to Chemical Formula 2-4.

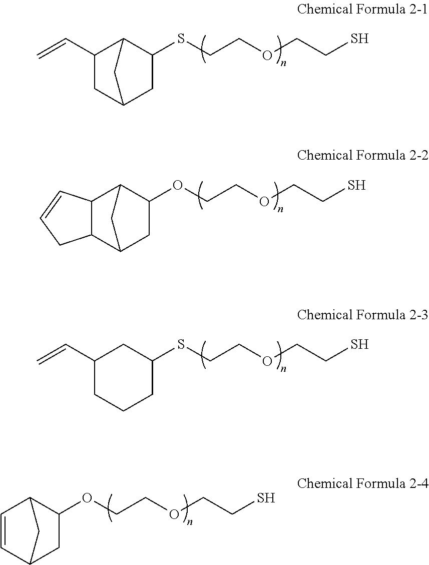

In Chemical Formula 2-1 to Chemical Formula 2-4,
n is an integer between 2 and 10.

The curable composition may be a solvent-free curable composition.

The solvent-free curable composition may include 5 wt % to 60 wt % of the quantum dot and 40 wt % to 95 wt % of the polymerizable compound, based on a total amount of the solvent-free curable composition.

The curable composition may further include a polymerization initiator, a light diffusing agent, a polymerization inhibitor or a combination thereof.

The light diffusing agent may include barium sulfate, calcium carbonate, titanium dioxide, zirconia, or a combination thereof.

The curable composition may further include malonic acid; 3-amino-1,2-propanediol; a silane coupling agent; a leveling agent; a fluorinated surfactant; or a combination thereof.

The quantum dot may include a cadmium-free light emitting material.

The quantum dot may have a core/shell structure of InP/ZnS or a core/first shell/second shell structure of InP/ZnSe/ZnS.

The quantum dot may include a core including Ag, In, Ga, and S; and a shell including at least two selected from Ag, Ga, Zn, and S.

The curable composition may further include a solvent.

The curable composition may include 1 wt % to 40 wt % of the quantum dot; 1 wt % to 20 wt % of the polymerizable compound; and 40 wt % to 80 wt % of the solvent, based on a total weight of the curable composition.

Some example embodiments provide a cured layer produced using the curable composition.

Some example embodiments provide a display device including the cured layer.

Other embodiments are included in the following detailed description.

By surface-modifying the quantum dots in a quantum dot-containing curable composition with a quantum dot surface-modifying material having an unprecedented composition, the reliability and optical properties of the quantum dot-containing curable composition can be improved.

### DETAILED DESCRIPTION

Hereinafter, embodiments of the present disclosure are described in more detail. However, these embodiments are examples, and this disclosure is not limited thereto.

As used herein, if (e.g., when) specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group (or a C1 to C20 heterocycloalkenyl group), “aryl group” refers to a C6 to C20 aryl group, “arylalkyl group” refers to a C6 to C20 arylalkyl group (or a C7 to C20 arylalkyl group), “alkylene group” refers to a C1 to C20 alkylene group, “arylene group” refers to a C6 to C20 arylene group, “alkylarylene group” refers to a C6 to C20 alkylarylene group (or a C7 to C20 alkylarylene group_, “heteroarylene group” refers to a C3 to C20 heteroarylene group (or a C1 to C20 heteroarylene group), and “alkoxylene group” refers to a C1 to C20 alkoxylene group.

As used herein, if (e.g., when) specific definition is not otherwise provided, “substituted” refers to replacement of at least one hydrogen atom by a substituent selected from a halogen atom (F, Cl, Br, or I), a hydroxy group, a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, if (e.g., when) specific definition is not otherwise provided, “hetero” refers to inclusion of at least one heteroatom of N, O, S, and P, in the chemical formula.

As used herein, if (e.g., when) specific definition is not otherwise provided, “(meth)acrylate” refers to both “acrylate” and “methacrylate,” and “(meth)acrylic acid” refers to “acrylic acid” and “methacrylic acid.”

As used herein, if (e.g., when) specific definition is not otherwise provided, the term “combination” refers to mixing and/or copolymerization.

As used herein, if (e.g., when) a definition is not otherwise provided, hydrogen is bonded at the position if (e.g., when) a chemical bond is not drawn in chemical formula where supposed to be given.

In embodiments, as used herein, if (e.g., when) a definition is not otherwise provided, “*” refers to a linking point with the same or different atom or chemical formula.

A quantum dot-containing curable composition according to embodiments of the present disclosure may use a surface-modifying material having a novel structure to surface-modify the quantum dot, achieving high heat/light resistance, compared to an other quantum dot-containing curable composition.

According to a recent trend in in the display field where a light source is being replaced from organic light-emitting diodes (OLED) to micro light-emitting diode (LED), light resistance of a film mounted inside the display becomes more important than ever. Accordingly, light resistance of a cured layer formed by curing the quantum dot-containing curable composition also becomes very important to improve, but an other quantum dot surface-modifying material alone fails in securing excellent film light resistance not enough to be used for the micro LED light source.

In general, in order to improve a curing rate of the quantum dot-containing curable composition, a high-sensitivity initiator and/or a multi-functional monomer, and/or the like are additionally used, and the above existing art, which select a set or specific configuration, may improve one characteristic among all characteristics of the quantum dot-containing curable composition such as dispersion, heat resistance, and the curing rate but deteriorates the other characteristics excluding the improved characteristics. Regarding the characteristics of the quantum dot-containing curable composition, there has been no known technology for a quantum dot-containing curable composition capable of maintaining low viscosity and realizing high light resistance.

For example, the existing technology so far includes a method of encapsulating the surfaces of the quantum dots with a polymer including a heat-resistant functional group or a siloxane (or TEOS, or the like)-based organic material, or the like, or encapsulating the surfaces of the quantum dots with aluminum, titanium, or an oxide thereof. Attempts have recently been made to simultaneously increase luminance and durability by doping a small amount of a transition metal (Cu, Mg, or the like) component in the quantum dot synthesis.

However, the above methods are still under academic study and too far away to actually apply to a display. In general, for displays that use quantum dots, efforts are made to increase the intensity of the light source to improve luminance. However, if (e.g., when) the luminance is improved by increasing the intensity of the light source, the stability of the quantum dot particles will decrease, which inevitably leads to the technical challenge of improving the reliability of the panel.

Accordingly, the inventors of the present disclosure conducted repeated research and completed a curable composition having excellent heat/light resistance reliability by increasing the dispersibility of quantum dots. For example, a curable composition according to some example embodiments includes (A) a quantum dot including a functional group represented by Chemical Formula 1; and (B) a polymerizable compound.

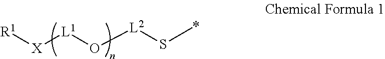

In Chemical Formula 1,
X is a sulfur atom or an oxygen atom,
R¹ is a monovalent functional group including a reactive group and a C3 to C20 cycloalkane ring,
L¹ and L² are each independently a substituted or unsubstituted C1 to C20 alkylene group, and
n is an integer between 2 and 10.

For example, in Chemical Formula 1, n may be an integer from 2 to 8.

For example, the reactive group may include a carbon-carbon double bond, an epoxy group, or a combination thereof.

Hereinafter, each component constituting the curable composition according to some example embodiments is further described.

### Quantum Dot

The most efficient ligand capable of passivating the surfaces of the quantum dots as an organic material ligand is believed to be a ligand having a thiol group, wherein a carboxylic acid-type ligand has relatively weak interaction with the surfaces of the quantum dots, and a phosphoric acid-type ligand has sufficient dispersibility of the quantum dots but a problem of lowering efficiency (causing color changes).

Because display technologies have been developed from LCD in the past to OLED, NED, and recent micro LED, which gradually increase intensity of blue light, the durability (for example, heat resistance and light resistance) of the quantum dots also needs to be significantly improved, compared with the current level.

Accordingly, the present disclosure applies a thiol-based ligand including a bulky cycloalkyl group (including a fused ring group) having a carbon-carbon double bond and/or an epoxy group as a reactive group at a terminal end and having a high binding energy with the quantum dot surface for effective passivation of the quantum dot surface, while concurrently (e.g., simultaneously) controlling the structure so that the linking group between the thiol group and the cycloalkyl group is suitably or necessarily composed of a highly polar oxyalkylene group, so that a quantum dot-containing curable composition having excellent heat/light resistance reliability, which maintains the initial luminous efficiency even if (e.g., when) exposed to strong blue light such as micro LED for a long period of time, and if (e.g., when) the quantum dot-containing curable composition surface-modified with the above ligand is mounted on a display panel in a single-film state. The oxyalkylene group having high polarity may improve dispersibility of the quantum dots, and under this premise, the light resistance reliability may be improved by the reactive group attached to the bulky cycloalkyl group (including a fused ring group) at the terminal end. If (e.g., when) other linking groups such as an ester group and/or the like are included as the linking group in addition to the oxyalkylene group, the dispersibility of the quantum dots may not only be deteriorated, but also heat resistance, light resistance, optical properties, and/or the like may be deteriorated.

For example, in Chemical Formula 1, R¹ may be represented by any one selected from Chemical Formulas R-1 to R-3.

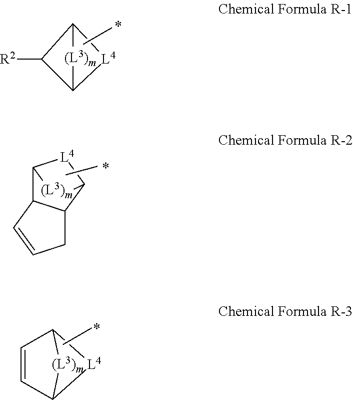

In Chemical Formulas R-1 to R-3,
R² is a ‘substituted or unsubstituted vinyl group’, a ‘substituted or unsubstituted epoxy group’, or a ‘C1 to C20 alkyl group substituted with an epoxy group, and/or a vinyl group,’
L³ and L⁴ are each independently a substituted or unsubstituted C1 to C10 alkylene group, and
m is an integer of 0 or 1.

Because the bulkier the cycloalkane ring of R¹ is, the better it can protect the quantum dots from external light, it is beneficial or advantageous for R¹ to be in the form of a fused ring including a cycloalkane ring, and therefore, in Chemical Formulas R-1 and R-2, m may be an integer of 1. In embodiments, it may also be beneficial or advantageous in terms of improving reliability.

For example, the functional group represented by Chemical Formula 1 may be represented by any one selected from Chemical Formula 1-1 to Chemical Formula 1-4, but is not necessarily limited thereto.

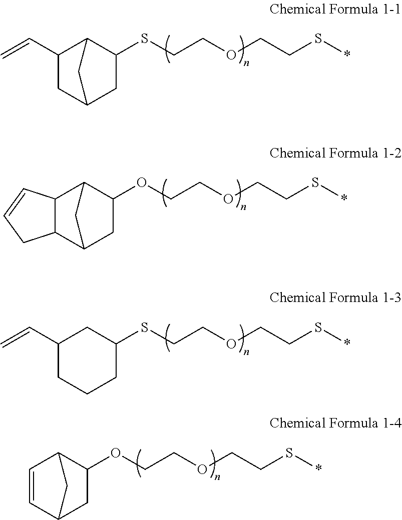

In Chemical Formula 1-1 to Chemical Formula 1-4,
n is an integer from 2 to 10, for example, an integer from 2 to 8.

In embodiments, the functional group represented by Chemical Formula 1 may be derived from (e.g., formed from) a compound represented by Chemical Formula 2.

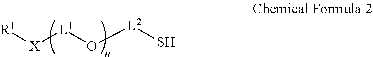

In Chemical Formula 2,
X is a sulfur atom or an oxygen atom,
R¹ is a monovalent functional group including a reactive group and a C3 to C20 cycloalkane ring,
L¹ and L² are each independently a substituted or unsubstituted C1 to C20 alkylene group, and
n is an integer from 2 to 10, for example, an integer from 2 to 8.

For example, a curable composition according to some example embodiments includes (A) a quantum dot surface-modified with a surface-modifying material; and (B) a polymerizable compound, wherein the surface-modifying material may include a compound represented by Chemical Formula 2.

The definition of R¹ may be as described above. In embodiments, in Chemical Formula 2, the definitions of the reactive groups, R¹, L¹, L², and n may also be as described above.

For example, the compound represented by Chemical Formula 2 may be represented by any one selected from Chemical Formula 2-1 to Chemical Formula 2-4, but is not necessarily limited thereto.

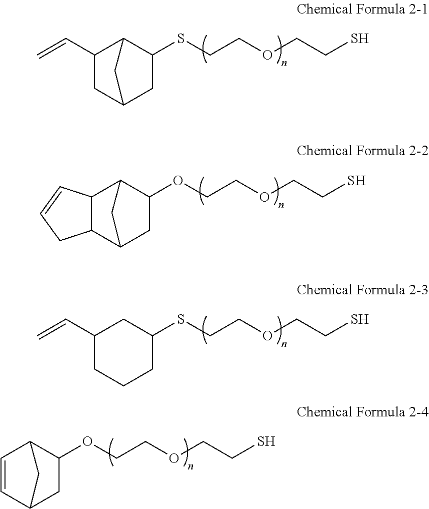

In Chemical Formula 2-1 to Chemical Formula 2-4,
n is an integer from 2 to 10, for example, an integer from 2 to 8.

If (e.g., when) the quantum dots surface-modified with the surface-modifying material are added to a polymerizable compound further described herein and stirred, a very transparent dispersion may be obtained, which is a criterion for confirming that the surface-modification of the quantum dots is very good.

For example, the quantum dot may have a maximum fluorescence emission wavelength between 500 nm and 680 nm.

For example, if (e.g., when) the curable composition according to some example embodiments is a solvent-free curable composition, the quantum dots may be included in an amount of 5 wt % to 60 wt %, for example 10 wt % to 60 wt %, for example 20 wt % to 60 wt %, or, for example, 30 wt % to 50 wt %. If (e.g., when) the quantum dots are included within the above ranges, a high light retention rate and light efficiency can be achieved even after curing.

For example, if (e.g., when) the curable composition according to some example embodiments is a curable composition including a solvent, the quantum dots may be included in an amount of 1 wt % to 40 wt %, or, for example, 3 wt % to 30 wt %, based on a total amount of the curable composition. If (e.g., when) the quantum dots are included within the above ranges, the light conversion rate is improved and pattern characteristics and development characteristics are not impaired, so that excellent processability may be obtained.

Up to now, quantum dot-containing curable compositions (inks) have been developed by specializing in thiol-based binders or monomers that have good compatibility with quantum dots, and are even being commercialized.

For example, the quantum dots absorb light in a wavelength region of 360 nm to 780 nm, or, for example, 400 nm to 780 nm and emits fluorescence in a wavelength region of 500 nm to 700 nm, or, for example, 500 nm to 580 nm, or emits fluorescence in a wavelength region of 600 nm to 680 nm. In embodiments, the quantum dots may have a maximum fluorescence emission wavelength (fluorescence λₑₘ) at 500 nm to 680 nm.

The quantum dots may each independently have a full width at half maximum (FWHM) of 20 nm to 100 nm, for example 20 nm to 50 nm. If (e.g., when) the quantum dots have a full width at half maximum (FWHM) of the ranges, color reproducibility is increased if (e.g., when) used as a color material in a color filter due to high color purity.

The quantum dots may each independently be an organic material, an inorganic material, or a hybrid (mixture) of an organic material and an inorganic material.

The quantum dots may each independently be composed of a core and a shell around (e.g., surrounding) the core, and the core and the shell may each independently have a structure of a core, core/shell, core/first shell/second shell, alloy, alloy/shell, and/or the like, which is composed of a Group II-IV element, a Group Ill-V element, and/or the like, but are not limited thereto.

For example, the core may include at least one material selected from CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell around (e.g., surrounding) the core may include at least one material selected from CdSe, ZnSe, ZnS, ZnTe, CdTe, PbS, TiO, SrSe, HgSe, and an alloy thereof, but is not necessarily limited thereto.

In some example embodiments, because an interest in the natural environment has been recently much increased over substantially the whole world, and a restriction of a toxic material also has been fortified, a cadmium-free light emitting material (InP/ZnS, InP/ZnSe/ZnS, etc.) having little low quantum efficiency (quantum yield) but being environmentally-friendly instead of a light emitting material having a cadmium-based core is used, but not necessarily limited thereto. In embodiments, the term “cadmium-free” means substantially free or completely free of cadmium, where substantially free means that the referenced component is present, if at all, only as an incidental impurity.

In some example embodiments, the quantum dot may be a quantum dot including a core including Ag, In, Ga, and S; and a shell including at least two (or at least three) selected from Ag, Ga, Zn, and S. At this time, the quantum dot may have one or more ligands. For example, the quantum dot may include, but is not necessarily limited to, a first ligand including a halide, a second ligand including an alkyl group and/or an alkoxy amine group, or a ligand of a combination thereof, but is not necessarily limited thereto.

In embodiments of the quantum dots of the core/shell structure, an entire size including the shell (an average particle diameter) may be 1 nm to 15 nm, or, for example, 5 nm to 15 nm.

For example, the quantum dots may each independently include red quantum dots, green quantum dots, or a combination thereof. The red quantum dots may each independently have an average particle diameter of 10 nm to 15 nm. The green quantum dots may each independently have an average particle diameter of 5 nm to 8 nm.

In embodiments, for dispersion stability of the quantum dot, the curable composition according to some example embodiments may further include a dispersant. The dispersant helps provide uniform (e.g., substantially uniform) dispersibility of light conversion materials such as quantum dots in the curable composition and may include a non-ionic, anionic, and/or cationic dispersant. For example, the dispersant may be polyalkylene glycol and/or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine and/or the like, and they may be used alone or in a mixture of two or more. The dispersant may be used in an amount of 0.1 wt % to 100 wt %, for example 10 wt % to 20 wt % based on a solid content of the light conversion material such as quantum dots.

### Polymerizable Compound

The curable composition according to some example embodiments may include a polymerizable compound, and the polymerizable compound may have a carbon-carbon double bond at a terminal end.

The polymerizable compound having the carbon-carbon double bond at the terminal end may be included in an amount of 40 wt % to 95 wt %, for example, 50 wt % to 90 wt %, based on a total amount of the solvent-free curable composition. If (e.g., when) the polymerizable compound having the carbon-carbon double bond at the terminal end is included within the above ranges, a solvent-free curable composition having a viscosity that enables ink-jetting may be prepared and the quantum dots in the prepared solvent-free curable composition may have improved dispersibility, thereby improving optical characteristics.

For example, the polymerizable compound having the carbon-carbon double bond at the terminal end may have a molecular weight of 170 g/mol to 1,000 g/mol. If (e.g., when) the polymerizable compound having the carbon-carbon double bond at the terminal end has a molecular weight within the above range, it may be beneficial or advantageous for ink-jetting because it does not increase a viscosity of the composition without hindering the optical characteristics of the quantum dots.

For example, the polymerizable compound having the carbon-carbon double bond at the terminal end may be represented by Chemical Formula 3, but is not necessarily limited thereto.

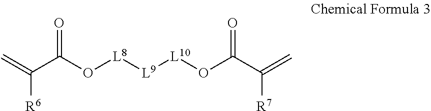

In Chemical Formula 3,
R⁶ and R⁷ are each independently a hydrogen atom or a substituted or unsubstituted C1 to C10 alkyl group,
L⁸ and L¹⁰ are each independently a single bond or a substituted or unsubstituted C1 to C10 alkylene group,
L⁹ is a substituted or unsubstituted C1 to C10 alkylene group, a substituted or unsubstituted C3 to C20 cycloalkylene group, or an ether group (*—O—*).

For example, the polymerizable compound having the carbon-carbon double bond at the terminal end may be represented by Chemical Formula 4-1, Chemical Formula 3-2 or Chemical Formula 3-3, but is not necessarily limited thereto.

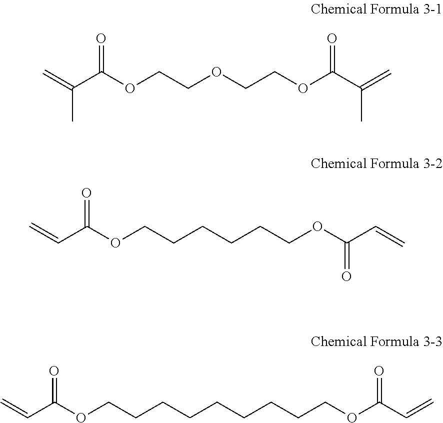

For example, the polymerizable compound having the carbon-carbon double bond at the terminal end may further include ethylene glycoldiacrylate, triethylene glycoldiacrylate, 1,4-butanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethylolpropanetriacrylate, novolac epoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof in addition to the aforementioned compound of Chemical Formula 3-1, Chemical Formula 3-2 or Chemical Formula 3-3.

In embodiments, together with the polymerizable compound having the carbon-carbon double bond at the terminal end, a generally-used monomer of any suitable thermosetting or photocurable composition may be further included. For example, the monomer further include an oxetane-based compound such as bis[1-ethyl (3-oxetanyl)]methyl ether, and/or the like.

In embodiments, if (e.g., when) the curable composition includes a solvent, the polymerizable compound may be included in an amount of 1 wt % to 20 wt %, 1 wt % to 15 wt %, or, for example, 5 wt % to 15 wt % based on a total amount of the curable composition. If (e.g., when) the above polymerizable compound is included within the above ranges, the optical properties of the quantum dot can be improved, and in the pattern formation process, suitable or sufficient curing occurs upon exposure, so that reliability is improved, and the heat resistance, light resistance, chemical resistance, resolution, and adhesion of the pattern are also improved.

In embodiments, if (e.g., when) the curable composition includes a solvent, the polymerizable compound may be a monofunctional or polyfunctional ester of (meth)acrylic acid having at least one ethylenically unsaturated double bond.

Because the polymerizable compound has the ethylenically unsaturated double bond, suitable or sufficient polymerization occurs upon exposure in the pattern forming process, thereby forming a pattern having excellent heat resistance, light resistance, and chemical resistance.

Examples of the polymerizable compound used in the solvent-type curable composition may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolacepoxy (meth)acrylate, and the like.

Examples of commercially available products of the polymerizable compound are as follows. Examples of the monofunctional esters of the (meth)acrylic acid may include Aronix M-101®, M-111®, M-114® from Toagosei Chemical Industry Co., Ltd.; KAYARAD TC-110S®, TC-120S® from Nihon Kayaku Co., Ltd.; V-158®, V-2311® from Osaka Yuki Chemical Industry Co., Ltd. Examples of the bifunctional esters of the (meth)acrylic acid include Aronix M-210®, M-240®, M-6200® from Toagosei Chemical Industry Co., Ltd.; KAYARAD HDDA®, HX-220®, R-604® from Nihon Kayaku Co., Ltd.; V-260®, V-312®, V-335 HP® from Osaka Yuki Chemical Industry Co., Ltd. Examples of the trifunctional ester of the (meth)acrylic acid may include Aronix M-309®, DONG M-400®, DONG M-405®, DONG M-450®, DONG M-7100®, DONG M-8030®, DONG M-8060®, etc. from Toagosei Chemical Industry Co., Ltd.; KAYARAD TMPTA®, DONG DPCA-20®, DONG-30®, DONG-60®, DONG-120®, etc. from Nihon Kayaku Co., Ltd.; V-295®, DONG-300®, DONG-360®, DONG-GPT®, DONG-3PA®, DONG-400®, etc. from Osaka Yuki Kayaku Industry Co., Ltd. The products may be used alone or in combination of two or more.

The polymerizable compound may also be used by treating it with an acid anhydride to provide better developability.

### Light Diffusing Agent

The curable composition according to some example embodiments may further include a light diffusing agent.

For example, the light diffusing agent may include barium sulfate (BaSO₄), calcium carbonate (CaCO₃), titanium dioxide (TiO₂), zirconia (ZrO₂), or a combination thereof.

The light diffusing agent may reflect unabsorbed light in the aforementioned quantum dots and allows the quantum dots to absorb the reflected light again. For example, the light diffusing agent may increase an amount of light absorbed by the quantum dots and increase light conversion efficiency of the curable composition.

The light diffusing agent may have an average particle diameter (D₅₀) of 150 nm to 250 nm, or, for example, 180 nm to 230 nm. If (e.g., when) the average particle diameter of the light diffusing agent is within the above ranges, it may have a better light diffusing effect and increase light conversion efficiency.

The light diffusing agent may be included in an amount of 1 wt % to 20 wt %, for example, 2 wt % to 15 wt %, or, for example, 2 wt % to 10 wt % based on a total amount of the curable composition. If (e.g., when) the light diffusing agent is included in an amount of less than 1 wt % based on a total amount of the curable composition, it is difficult to expect a light conversion efficiency improvement effect due to the use of the light diffusing agent, while if (e.g., when) it is included in an amount of greater than 20 wt %, there is a possibility that the quantum dots may be sedimented.

The curable composition according to some example embodiments may further include a polymerization initiator, for example, a photopolymerization initiator, a thermal polymerization initiator, or a combination thereof.

The photopolymerization initiator may be a generally-used initiator for a photosensitive resin composition, for example, an acetophenone-based compound, a benzophenone-based compound, a thioxanthone-based compound, a benzoin-based compound, a triazine-based compound, an oxime-based compound, an aminoketone-based compound, and/or the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloro methyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be O-acyloxime-based compound, 2-(O-benzoyloxime)-1-[4-(phenylthio)phenyl]-1,2-octandione, 1-(0-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

Examples of the aminoketone-based compound may be 2-benzyl-2-dimethylamino-1-(4-morpholinophenyl)-butanone-1, and the like.

The photopolymerization initiator may further include a carbazole-based compound, a diketone-based compound, a sulfonium borate-based compound, a diazo-based compound, an imidazole-based compound, a biimidazole-based compound, and/or the like, besides the other compounds disclosed herein.

The photopolymerization initiator may be used with a photosensitizer capable of causing a chemical reaction by absorbing light and becoming excited and then, transferring its energy to initiate the chemical reaction.

Examples of the photosensitizer may be tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may be peroxide, such as, for example, benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and the like, for example 2,2′-azobis-2-methylpropinonitrile, but are not necessarily limited thereto and any suitable one generally used in the art may be used.

The polymerization initiator may be included in an amount of 0.01 wt % to 10 wt %, or, for example, 2 wt % to 8 wt % based on a total amount of the curable composition. If (e.g., when) the polymerization initiator is included in the above ranges, it is possible to obtain excellent reliability due to suitable or sufficient curing during exposure and/or thermal curing and to prevent or reduce deterioration of transmittance due to non-reaction initiators, thereby preventing or reducing deterioration of optical characteristics of the quantum dots.

### Binder Resin

The curable composition according to some example embodiments may further include a binder resin.

The binder resin may include an acrylic resin, a cardo-based resin, an epoxy resin, or a combination thereof.

The acrylic resin may be a copolymer of a first ethylenic unsaturated monomer and a second ethylenic unsaturated monomer that is copolymerizable therewith, and may be resin including at least one acryl-based repeating unit.

Examples of the acrylic resin may be polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto, and may be used alone or as a mixture of two or more.

A weight average molecular weight of the acrylic resin may be 5,000 g/mol to 15,000 g/mol. If (e.g., when) the acrylic resin has a weight average molecular weight within the above range, close contacting properties to a substrate, physical and chemical properties are improved, and a viscosity is suitable or appropriate.

An acid value of the acrylic resin may be 80 mgKOH/g to 130 mgKOH/g. If (e.g., when) the acrylic resin has an acid value within the above range, excellent resolution of a pixel may be obtained.

The cardo-based resin may be any suitable one used in a curable resin (or photosensitive resin) composition, for example, one suggested in Korean Patent Publication No. 10-2018-0067243, the content of which directed to the cardo-based resin is hereby incorporated by reference, may be used, but is not limited thereto.

The cardo-based resin may be, for example prepared by mixing at least two of a fluorene-containing compound such as 9,9-bis(4-oxiranylmethoxyphenyl)fluorene; an anhydride compound such as benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and tetrahydrophthalic anhydride; a glycol compound such as ethylene glycol, propylene glycol, and polyethylene glycol; an alcohol compound such as methanol, ethanol, propanol, n-butanol, cyclohexanol, and benzylalcohol; a solvent-based compound such as propylene glycol methylethylacetate, and N-methylpyrrolidone; a phosphorus compound such as triphenylphosphine; and an amine or ammonium salt compound such as tetramethylammonium chloride, tetraethylammonium bromide, benzyldiethylamine, triethylamine, tributylamine, and/or benzyl triethylammonium chloride.

A weight average molecular weight of the cardo-based binder resin may be 500 g/mol to 50,000 g/mol, or, for example 1,000 g/mol to 30,000 g/mol. If (e.g., when) the weight average molecular weight of the cardo-based binder resin is within the above ranges, a suitable or satisfactory pattern may be formed without a residue during a production of a cured layer and without losing a film thickness during development of the curable composition.

If (e.g., when) the binder resin is a cardo-based resin, the curable composition including the same, for example, the photosensitive resin composition, has excellent developability and sensitivity during photo-curing and thus, fine pattern-forming capability.

The epoxy resin may be a thermally polymerizable monomer and/or oligomer, and may include a compound having a carbon-carbon unsaturated bond and a carbon-carbon cyclic bond.

The epoxy resin may further include a bisphenol A epoxy resin, a bisphenol F epoxy resin, a phenol novolac epoxy resin, a cyclic aliphatic epoxy resin, and/or an aliphatic polyglycidyl ether, but is not necessarily limited thereto.

As commercially available products of the compounds, a bisphenyl epoxy resin may be YX4000, YX4000H, YL6121H, YL6640, and/or YL6677 of Yuka Shell Epoxy Co., Ltd.; a cresol novolac epoxy resin may be EOCN-102, EOCN-103S, EOCN-104S, EOCN-1020, EOCN-1025, and/or EOCN-1027 of Nippon Kayaku Co., Ltd. and/or EPIKOTE 180S75, and/or the like of Yuka Shell Epoxy Co., Ltd.; a bisphenol A epoxy resin may be EPIKOTE 1001, 1002, 1003, 1004, 1007, 1009, 1010, and/or 828 of Yuka Shell Epoxy Co., Ltd.; a bisphenol F epoxy resin may be EPIKOTE 807 and/or 834 of Yuka Shell Epoxy Co., Ltd.; a phenol novolac epoxy resin may be EPIKOTE 152, 154, and/or 157H65 of Yuka Shell Epoxy Co. and/or EPPN 201, 202 of Nippon Kayaku Co., Ltd. and/or EPPN 201, 202 of Nippon Kayaku Co., Ltd.; a cyclic aliphatic epoxy resin may be CY175, CY177, and/or CY179 of CIBA-GEIGY A.G Corp., ERL-4234, ERL-4299, ERL-4221 and/or ERL-4206 of U.C.C., Showdyne 509 of Showa Denko K.K., Araldite CY-182, CY-192 and/or CY-184 of CIBA-GEIGY A.G Corp., EPICLON 200 and/or 400 of Dainippon Ink & Chemicals Inc., EPIKOTE 871 and/or 872, and/or EP1032H60 of Yuka Shell Epoxy Co., Ltd., ED-5661 and/or ED-5662 of Celanese Coating Corporation; an aliphatic polyglycidylether may be EPIKOTE 190P and/or 191P of Yuka Shell Epoxy Co., Ltd., EPOLITE 100MF of Kyoeisha Yushi Kagaku Kogyo Co., Ltd., EPIOL TMP of Nihon Yushi K. K., and/or the like.

For example, if (e.g., when) the curable composition according to some example embodiments is a solvent-free curable composition, the binder resin may be included in an amount of 0.5 wt % to 10 wt %, for example, 1 wt % to 5 wt %, based on a total amount of the curable composition. In embodiments, the heat resistance and the chemical resistance of the solvent-free curable composition may be improved, as well as the storage stability of the composition.

For example, if (e.g., when) the curable composition according to some example embodiments is a curable composition including a solvent, the binder resin may be included in an amount of 1 wt % to 30 wt %, or, for example, 3 wt % to 20 wt %, based on a total amount of the curable composition. In embodiments, it may improve pattern characteristics, heat resistance, and chemical resistance.

### Other Additives

For stability and dispersion improvement of the quantum dot, the curable composition according to some example embodiments may further include a polymerization inhibitor.

The polymerization inhibitor may include a hydroquinone-based compound, a catechol-based compound, or a combination thereof, but is not necessarily limited thereto. If (e.g., when) the curable composition according to some example embodiments further includes the hydroquinone-based compound, the catechol-based compound, or the combination thereof, room temperature cross-linking during exposure after coating the curable composition may be prevented or reduced.

For example, the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof, but are not necessarily limited thereto.

The hydroquinone-based compound, the catechol-based compound, or the combination thereof may be used in a form of dispersion. The polymerization inhibitor in a form of dispersion may be included in an amount of 0.001 wt % to 3 wt %, or, for example 0.01 wt % to 2 wt % based on a total amount of the curable composition. If (e.g., when) the polymerization inhibitor is included in the above ranges, passage of time at room temperature may be solved or stabilized and concurrently (e.g., simultaneously) sensitivity deterioration and surface delamination phenomenon may be prevented or reduced.

In embodiments, the curable composition according to some example embodiments may further include malonic acid; 3-amino-1,2-propanediol; a silane-based coupling agent; a leveling agent; a fluorine-based surfactant; or a combination thereof in order to improve heat resistance and reliability.

For example, the curable composition according to embodiment may further include a silane-based coupling agent having a reactive substituent such as a vinyl group, a carboxyl group, a methacryloxy group, an isocyanate group, an epoxy group, and/or the like in order to improve close contacting properties with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-(epoxycyclohexyl)ethyltrimethoxysilane, and the like, and these may be used alone or in a mixture of two or more.

The silane-based coupling agent may be used in an amount of 0.01 parts by weight to 10 parts by weight based on 100 parts by weight of the curable composition. If (e.g., when) the silane-based coupling agent is included within the above range, close contacting properties, storage capability, and the like are improved.

In embodiments, the curable composition may further include a surfactant, for example a fluorine-based surfactant as needed in order to improve coating properties and inhibit or reduce generation of spots, for example, improve leveling performance.

The fluorine-based surfactant may have a low weight average molecular weight of 4,000 g/mol to 10,000 g/mol, or, for example, 6,000 g/mol to 10,000 g/mol. In embodiments, the fluorine-based surfactant may have a surface tension of 18 mN/m to 23 mN/m (measured in a 0.1% polyethylene glycol monomethylether acetate (PGMEA) solution). If (e.g., when) the fluorine-based surfactant has a weight average molecular weight and a surface tension within the above ranges, leveling performance may be further improved, and excellent characteristics may be provided if (e.g., when) slit coating as high-speed coating is applied because film defects may be less generated by preventing or reducing a spot generation during the high-speed coating and suppressing or reducing a vapor generation.

Examples of the fluorine-based surfactant may be, BM-1000®, and/or BM-1100® (BM Chemie Inc.); MEGAFACE F 142D®, F 172®, F 173®, and/or F 183® Dainippon Ink Kagaku Kogyo Co., Ltd.); FLUORAD FC-135®, FLUORAD FC-170C®, FLUORAD FC-430®, and/or FLUORAD FC-431® (Sumitomo 3M Co., Ltd.); SURFLON S-112®, SURFLON S-113®, SURFLON S-131®, SURFLON S-141®, and/or SURFLON S-145® (ASAHI Glass Co., Ltd.); and/or SH-28PA®, SH-190®, SH-193®, SZ-6032®, and/or SF-8428®, and/or the like (Toray Silicone Co., Ltd.); F-482, F-484, F-478, F-554 and/or the like of DIC Co., Ltd.

In embodiments, the curable composition according to some example embodiments may include a silicone-based surfactant in addition to the fluorine-based surfactant. Examples of the silicone-based surfactant may be TSF400, TSF401, TSF410, TSF4440, and/or the like of Toshiba silicone Co., Ltd., but are not limited thereto.

The surfactant may be included in an amount of 0.01 parts by weight to 5 parts by weight, for example 0.1 parts by weight to 2 parts by weight based on 100 parts by weight of the curable composition. If (e.g., when) the surfactant is included within the above ranges, foreign materials are less produced in a sprayed composition.

In embodiments, the curable composition according to some example embodiments may further include other additives such as an antioxidant, a stabilizer, and/or the like in a set or predetermined amount, unless properties are deteriorated.

### Solvent

The curable composition according to some example embodiments may further include a solvent.

The solvent may for example include alcohols such as methanol, ethanol, and/or the like; glycol ethers such as ethylene glycol methylether, ethylene glycol ethylether, propylene glycol methylether, and/or the like; cellosolve acetates such as methyl cellosolve acetate, ethyl cellosolve acetate, diethyl cellosolve acetate, and/or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and/or the like; propylene glycol alkylether acetates such as propylene glycol monomethylether acetate, propylene glycol propylether acetate, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and the like; hydroxy acetic acid alkyl esters such as methyl hydroxyacetate, ethyl hydroxyacetate, butyl hydroxyacetate, and/or the like; acetic acid alkoxyalkyl esters such as methoxymethyl acetate, methoxyethyl acetate, methoxybutyl acetate, ethoxymethyl acetate, ethoxyethyl acetate, and/or the like; 3-hydroxypropionic acid alkyl esters such as methyl 3-hydroxypropionate, ethyl 3-hydroxypropionate, and/or the like; 3-alkoxypropionic acid alkyl esters such as methyl 3-methoxypropionate, ethyl 3-methoxypropionate, ethyl 3-ethoxypropionate, methyl 3-ethoxypropionate, and/or the like; 2-hydroxypropionic acid alkyl ester such as methyl 2-hydroxypropionate, ethyl 2-hydroxypropionate, propyl 2-hydroxypropionate, and/or the like; 2-alkoxypropionic acid alkyl esters such as methyl 2-methoxypropionate, ethyl 2-methoxypropionate, ethyl 2-ethoxypropionate, methyl 2-ethoxypropionate, and/or the like; 2-hydroxy-2-methylpropionic acid alkyl esters such as methyl 2-hydroxy-2-methylpropionate, ethyl 2-hydroxy-2-methylpropionate, and/or the like; 2-alkoxy-2-methylpropionic acid alkyl esters such as methyl 2-methoxy-2-methylpropionate, ethyl 2-ethoxy-2-methylpropionate, and/or the like; esters such as 2-hydroxyethyl propionate, 2-hydroxy-2-methylethyl propionate, hydroxyethyl acetate, methyl 2-hydroxy-3-methylbutanoate, and/or the like; and/or ketonate esters such as ethyl pyruvate, and/or the like, and in embodiments, may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and/or the like, but is not limited thereto.

For example, the solvent may be suitably or desirably glycol ethers such as ethylene glycol monoethylether, ethylene diglycolmethylethylether, and/or the like; ethylene glycol alkylether acetates such as ethyl cellosolve acetate, and/or the like; esters such as 2-hydroxy ethyl propionate, and/or the like; carbitols such as diethylene glycol monomethylether, and/or the like; propylene glycol alkylether acetates such as propylene glycol monomethylether acetate, propylene glycol propylether acetate, and/or the like; alcohols such as ethanol, cyclohexyl acetate, or a combination thereof.

For example, the solvent may be a high-boiling point polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, cyclohexyl acetate, or a combination thereof.

The solvent may be included in an amount of 40 wt % to 80 wt %, or, for example, 45 wt % to 80 wt %, based on a total amount of the curable composition. If (e.g., when) the solvent is within the above ranges, the solvent-type curable composition has suitable or appropriate viscosity and thus may have excellent coating property if (e.g., when) coated in a large area through spin-coating and/or slit-coating.

Some example embodiments provide a cured layer produced using the aforementioned curable composition, a color filter including the cured layer, and a display device including the color filter. For example, the display device may include a micro LED light source.

One embodiment of the methods for producing the cured layer includes coating the curable composition and solvent-type curable composition on a substrate using an ink-jet spraying method to form a pattern (S1); and curing the pattern (S2).

### (S1) Formation of Pattern

The curable composition may suitably or desirably be coated to be 0.5 μm to 20 μm on a substrate in an ink-jet spraying method. The ink-jet spraying method may form a pattern by spraying a single color per each nozzle and thus repeating the spraying as many times as the needed or desired number of colors, but the pattern may be formed by concurrently (e.g., simultaneously) spraying the needed or desired number of colors through each ink-jet nozzle in order to reduce processes.

### (S2) Curing

The obtained pattern is cured to obtain a pixel. In embodiments, the curing method may be thermal curing and/or photocuring process. The thermal curing process may be performed at greater than or equal to 100° C., suitably or desirably, in a range of 100° C. to 300° C., and, for example, in a range of 160° C. to 250° C. The photocuring process may include irradiating an actinic ray such as a UV ray of 190 nm to 450 nm, or, for example 200 nm to 400 nm. As light sources used in the irradiation, low-pressure mercury lamps, high-pressure mercury lamps, ultra-high-pressure mercury lamps, metal halide lamps, argon gas lasers, i-line, KrF, ArF, I—ArF, EUV, X-rays, and/or electron beams may be used depending on the embodiment.

An embodiment of a method of producing the cured layer may include producing a cured layer using the aforementioned curable composition by a lithography method as follows.

### (1) Coating and Film Formation

The aforementioned curable composition is coated to have a suitable or desired thickness, for example, a thickness from 2 μm to 10 μm, on a substrate which undergoes a set or predetermined pretreatment, using a spin and/or slit coating method, a roll coating method, a screen-printing method, an applicator method, and/or the like. Then, the coated substrate is heated at a temperature of 70° C. to 90° C. for 1 minute to 10 minutes to remove a solvent and to form a film.

### (2) Exposure

The resultant film is irradiated by an actinic ray such as a UV ray of 190 nm to 450 nm, or, for example, 200 nm to 400 nm after putting a mask having a set or predetermined shape to form a suitable or desired pattern. As light sources used in the irradiation, low-pressure mercury lamps, high-pressure mercury lamps, ultra-high-pressure mercury lamps, metal halide lamps, argon gas lasers, i-line, KrF, ArF, I—ArF, EUV, X-rays, and/or electron beams may be used depending on the embodiment.

An embodiment of an exposure process uses, for example, a light dose of 500 mJ/cm² or less (with a 365 nm sensor) if (e.g., when) a high-pressure mercury lamp is used. However, the light dose may suitably vary depending on types (or kinds) of each component of the curable composition, its combination ratio, and a dry film thickness.

### (3) Development

After the exposure process, an alkali aqueous solution is used to develop the exposed film by dissolving and removing an unnecessary or undesired part except the exposed part, forming an image pattern. In embodiments, if (e.g., when) the alkali developing solution is used for the development, a non-exposed region is dissolved, and an image color filter pattern is formed.

### (4) Post-Treatment

The developed image pattern may be heated again and/or irradiated by an actinic ray and/or the like for curing, in order to accomplish excellent quality in terms of heat resistance, light resistance, close contacting properties, crack-resistance, chemical resistance, high strength, storage stability, and the like.

Hereinafter, the subject matter of the present disclosure is illustrated in more detail with reference to examples. These examples, however, are not in any sense to be interpreted as limiting the scope of the present disclosure.

### (Synthesis of Surface-Modifying Materials)

### Synthesis Example 1-1

120 g of 5-vinyl-2-norbornene, 78.1 g of 2-mercaptoethanol, 0.3 g of AIBN, and 150 g of methanol were added to a round flask, heated to 60° C., and reacted for 6 hours, and then methanol was removed using a reduced pressure condenser. The obtained compound was transferred to a high-pressure reactor, 0.1 g of KOH was added to the compound obtained above, and the internal temperature was increased to 80° C. 176 g of ethylene oxide was slowly added and reacted while controlling the internal pressure. The compound obtained was placed in a two-neck round bottom flask and dissolved sufficiently in THF. At an internal temperature of 0° C., 44 g of NaOH and 100 mL of water were added and dissolved sufficiently until a clear solution was obtained. A solution of 210 g of para-toluene sulfonyl chloride dissolved in 300 mL of THE was slowly injected at 0° C. Herein, the injection proceeded for 2 hours, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. The obtained dried material was placed in a two-necked round bottom flask and stirred thoroughly in 500 mL of ethanol. Subsequently, 91.2 g of thiourea was added thereto and dispersed and then, refluxed at 80° C. for 12 hours. Then, an aqueous solution of 60 g of NaOH dissolved in 200 mL of water was injected, and after 5 more hours of reaction, an excessive amount of methylene chloride was added to dilute it. A hydrochloric acid solution was added and extraction, titration, moisture removal, and solvent removal were performed sequentially. By drying in a vacuum oven for 24 hours, a compound represented by Chemical Formula A-1 was obtained.

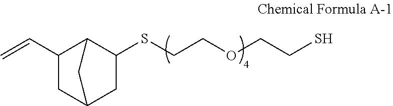

### Synthesis Example 2-1

150.22 g of hydroxydicyclopentadiene and 0.1 g of KOH were placed in a high-pressure reactor and the internal temperature was raised to 80° C. HDCP-4 was synthesized by slowly adding 176 g of ethylene oxide while controlling the internal pressure. 326.22 g of HDCP-4 was added in a two-neck round bottom flask and dissolved sufficiently in 800 mL of THF. At an internal temperature of 0° C., 44 g of NaOH and 100 mL of water were added and dissolved sufficiently until a clear solution was obtained. A solution of 210 g of para-toluene sulfonyl chloride dissolved in 300 mL of THE was slowly injected at 0° C. Herein, the injection proceeded for 2 hours, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 481.2 g of the obtained dried material was placed in a two-necked round bottom flask and stirred thoroughly in 500 mL of ethanol. Subsequently, 91.2 g of thiourea was added thereto and dispersed and then, refluxed at 80° C. for 12 hours. Then, an aqueous solution of 60 g of NaOH dissolved in 200 mL of water was injected, and after 5 more hours of reaction, an excessive amount of methylene chloride was added to dilute it. A hydrochloric acid solution was added and extraction, titration, moisture removal, and solvent removal were performed sequentially. By drying in a vacuum oven for 24 hours, a compound represented by Chemical Formula B-1 was obtained.

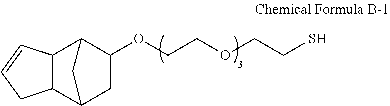

### Synthesis Example 3-1

After adding 108 g of 4-vinyl-1-cyclohexane, 78.1 g of 2-mercaptoethanol, 0.3 g of AIBN, and 150 g of methanol, the temperature was increased to 60° C. and after the reaction was performed for 6 hours, methanol was removed using a reduced pressure concentrator. The obtained compound was transferred to a high-pressure reactor, 0.1 g of KOH was added to the compound obtained above, and the internal temperature was increased to 80° C. 176 g of ethylene oxide was slowly added and reacted while controlling the internal pressure. The compound obtained was placed in a two-neck round bottom flask and dissolved sufficiently in THF. At 0° C., 44 g of NaOH and 100 mL of water were added thereto and dissolved sufficiently until a clear solution was obtained. A solution of 210 g of para-toluene sulfonyl chloride dissolved in 300 mL of THE was slowly injected at 0° C. Herein, the injection proceeded for 2 hours, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 510 g of the obtained dried material was placed in a two-necked round bottom flask and stirred thoroughly in 500 mL of ethanol. Subsequently, 91.2 g of thiourea was added thereto and dispersed and then, refluxed at 80° C. for 12 hours. Then, an aqueous solution obtained by dissolving 60 g of NaOH in 200 mL of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula C-1 was obtained.

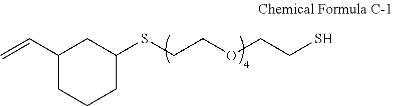

### Synthesis Example 4-1

124 g of 5-norbornen-2-methanol and 0.1 g of KOH were placed in a high-pressure reactor and the internal temperature was raised to 80° C. NBM-4 was synthesized by slowly adding 176 g of ethylene oxide while controlling the internal pressure. 300 g of NBM-4 was added in a two-neck round bottom flask and dissolved sufficiently in 800 mL of THF. At 0° C., 44 g of NaOH and 100 mL of water were added thereto and dissolved sufficiently until a clear solution was obtained. A solution of 210 g of para-toluene sulfonyl chloride dissolved in 300 mL of THE was slowly injected at 0° C. Herein, the injection proceeded for 2 hours, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 481.2 g of the obtained dried material was placed in a two-necked round bottom flask and stirred thoroughly in 500 mL of ethanol. Subsequently, 91.2 g of thiourea was added thereto and dispersed and then, refluxed at 80° C. for 12 hours. Then, an aqueous solution obtained by dissolving 60 g of NaOH in 200 mL of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula D-1 was obtained.

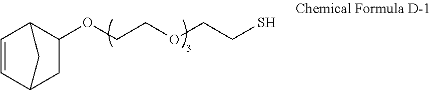

### Comparative Synthesis Example 1

100 g of polyethylene glycol ether (Hannong Chemicals Inc.) was placed in a two-neck round bottom flask and dissolved sufficiently in 300 mL of THF. At 0° C., 15.4 g of NaOH and 100 mL of water were added and dissolved sufficiently until a clear solution was obtained. A solution of 73 g of para-toluene sulfonyl chloride dissolved in 100 mL of THF was slowly injected at 0° C. Herein, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 50 g of the dried product was added in a two-necked round bottom flask and sufficiently stirred in 300 mL of ethanol. Subsequently, 27 g of thiourea was added thereto and dispersed and then, refluxed at 80° C. for 12 hours. Then, an aqueous solution obtained by dissolving 4.4 g of NaOH in 20 mL of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula W was obtained.

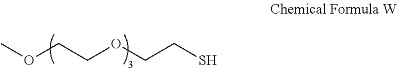

### Comparative Synthesis Example 2

100 g of polyethylene glycol phenyl ether (Hannong Chemicals Inc., Ph-4) was added to a two-necked round-bottom flask and dissolved thoroughly in 300 mL of THF. At 0° C., 15.4 g of NaOH and 100 mL of water were added and dissolved sufficiently until a clear solution was obtained. A solution of 73 g of para-toluene sulfonyl chloride dissolved in 100 mL of THE was slowly injected at 0° C. Herein, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 50 g of the dried product was added in a two-necked round bottom flask and sufficiently stirred in 300 mL of ethanol. Subsequently, 27 g of thiourea was added thereto and dispersed and then, refluxed at 80° C. for 12 hours. Then, an aqueous solution obtained by dissolving 4.4 g of NaOH in 20 mL of water was injected thereinto, while further stirring for 5 hours, an excessive amount of methylene chloride was added thereto and then, stirred, and a hydrochloric acid aqueous solution was added thereto, followed by extraction, titration, moisture removal, and solvent removal sequentially. By drying in a vacuum oven for 24 hours, a compound represented by Chemical Formula X was obtained.

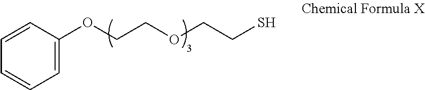

### Comparative Synthesis Example 3

102 g of tetrahydrofurfuryl alcohol and 0.1 g of KOH were placed in a high-pressure reactor and the internal temperature was raised to 80° C. THF-4 was synthesized by slowly adding 176 g of ethylene oxide while controlling the internal pressure. 278 g of THF-4 was added to a two-neck round bottom flask and dissolved sufficiently in 300 mL of THF. At an internal temperature of 0° C., 15.4 g of NaOH and 100 mL of water were added and dissolved sufficiently until a clear solution was obtained. A solution of 73 g of para-toluene sulfonyl chloride dissolved in 100 mL of THE was slowly injected at 0° C. Herein, the injection was performed for 1 hour, and the obtained mixture was stirred at room temperature for 12 hours. When a reaction was completed, an excessive amount of methylene chloride was added thereto and then, stirred, and a NaHCO₃ saturated solution was added thereto followed by extraction, titration, and moisture removal. After removing the solvent, drying was performed in a dry oven for 24 hours. 50 g of the dried product was added in a two-necked round bottom flask and sufficiently stirred in 300 mL of ethanol. Subsequently, 27 g of thiourea was added thereto and dispersed and then, refluxed at 80° C. for 12 hours. Then, an aqueous solution of 4.4 g of NaOH dissolved in 20 mL of water was injected, and after 5 more hours of reaction, an excessive amount of methylene chloride was added to dilute it. A hydrochloric acid solution was added and extraction, titration, moisture removal, and solvent removal were performed sequentially. By drying in a vacuum oven for 24 hours, a compound represented by Chemical Formula Y was obtained.

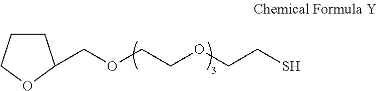

### Comparative Synthesis Example 4

150.22 g of hydroxydicyclopentadiene and 0.1 g of KOH were placed in a high-pressure reactor and the internal temperature were raised to 80° C. HDCP-4 was synthesized by slowly adding 176 g of ethylene oxide while controlling the internal pressure. The compound obtained was placed in a two-neck round bottom flask, 800 g of cyclohexane, 15 g of sulfuric acid, 120 g of thioglycolic acid, and 0.1 g of MHQ were added, the temperature were raised to 70° C., and the reaction was carried out for 12 hours while removing the H₂O produced. When H₂O was no longer produced, it was cooled to room temperature, washed with distilled water twice, neutralized with NaOH aqueous solution once, and washed with distilled water twice sequentially, and then the solvent was removed through reduced pressure drying to finally obtain a compound represented by Chemical Formula Z.

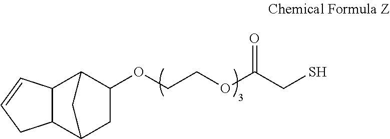

### Preparation of Quantum Dot

### Preparation Examples 1 to 4 and Comparative Preparation Examples 1 to 5

A magnetic bar was placed in a 3-neck round bottom flask and a green quantum dot dispersion solution (InP/ZnSe/ZnS, Hansol Chemical; quantum dot solid content 26 wt %) was added. The green quantum dots had oleic acid substituted on their surface. Here, the surface-modifying materials according to Synthesis Examples 1-1 to 4-1 and Comparative Synthesis Examples 1 to 4 were respectively added and stirred at 80° C. in a nitrogen atmosphere. After the reaction was completed, the resultant was cooled to room temperature (23° C.) and the quantum dot reaction solution was added to cyclohexane to obtain a precipitate. The precipitates were separated from the cyclohexane through centrifugation and sufficiently dried in a vacuum oven for one day to obtain surface-modified green quantum dots. The quantum dot of Comparative Preparation Example 1 was a quantum dot that had not been surface-modified, that is, a quantum dot with oleic acid substituted on the surface (e.g., unreacted oleic acid substituted on the surface).

### Preparation of Solvent-Free Curable Compositions

Based on the following respective components, curable compositions according to Examples 1 to 4 and Comparative Examples 1 to 4 were prepared.

### (A) Quantum Dot

(A-1) Green quantum dot surface-modified with the compound of Chemical Formula A-1 (Preparation Example 1)
(A-2) Green quantum dot surface-modified with the compound of Chemical Formula B-1 (Preparation Example 2)
(A-3) Green quantum dots surface-modified with the compound of Chemical Formula C-1 (Preparation Example 3)
(A-4) Green quantum dot surface-modified with the compound of above chemical formula D-1 (Preparation Example 4)
(A-5) Green quantum dots without surface modification (Comparative Preparation Example 1)
(A-6) Green quantum dots surface-modified with the compound of Chemical Formula W (Comparative Preparation Example 2)
(A-7) Green quantum dots surface-modified with the compound of Chemical Formula X (Comparative Preparation Example 3)
(A-8) Green quantum dots surface-modified with the compound of Chemical Formula Y (Comparative Preparation Example 4)
(A-9) Green quantum dots surface-modified with the compound of Chemical Formula Z (Comparative Preparation Example 5)

### (B) Polymerizable Compound

Compound represented by Chemical Formula 3-2 (M200, Miwon Chemical Co., Ltd.)

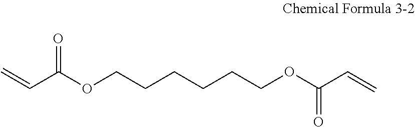 [SMILES: C=CC(=O)OCCCCCCOC(=O)C=C]

### (C) Photopolymerization Initiator

TPO-L (Polynetron Co.)

### (D) Light Diffusing Agent

Titanium dioxide dispersion (rutile type TiO₂; D50 (180 nm), solid content 50 wt %, Iridos Co., Ltd.)

### Examples 1 to 4 and Comparative Examples 1 to 5

The surface-modified green quantum dots and a polymerizable compound were mixed and stirred for 12 hours. A polymerization inhibitor was added thereto and then, stirred for 5 minutes. After adding a photopolymerization initiator thereto, a light diffusing agent was added thereto.

Referring to Example 1 as an example, 41 g of the surface-modified green quantum dots and 41 g of the compound represented by Chemical Formula 3-2 as the polymerizable compound were mixed and stirred to prepare a green quantum dot dispersion, and 11 g of another curable monomer represented by Chemical Formula 3-2 were added thereto and then, stirred for 5 minutes, and subsequently, 3 g of the photopolymerization initiator and 3 g of the light diffusing agent were added thereto and then, stirred, preparing a curable composition (ink).

The specific compositions are shown in Table 1 (unit: wt %) and Table 2 (unit: wt %).

TABLE 1

| | | Example 1 | Example 2 | Example 3 | Example 4 |
|---|---|---|---|---|---|
| Quantum | (A-1) | 41 | — | — | — |
| dot | (A-2) | — | 41 | — | — |
| | (A-3) | — | — | 41 | — |
| | (A-4) | — | — | — | 41 |

| | | | | |
|---|---|---|---|---|
| Polymerizable | 41 | 41 | 41 | 41 |
| compound (for | | | | |
| dispersion) | | | | |
| Polymerizable | 11 | 11 | 11 | 11 |
| compound | | | | |
| Photopolymerization | 3 | 3 | 3 | 3 |
| initiator | | | | |
| Light diffusing | 4 | 4 | 4 | 4 |
| agent | | | | |

TABLE 2

| | | Comparative | Comparative | Comparative | Comparative | Comparative |
|---|---|---|---|---|---|---|
| | | Example 1 | Example 2 | Example 3 | Example 4 | Example 5 |
| Quantum | (A-5) | 41 | — | — | — | — |
| dot | (A-6) | — | 41 | — | — | — |
| | (A-7) | — | — | 41 | — | — |
| | (A-8) | — | — | — | 41 | — |
| | (A-9) | — | — | — | — | 41 |

| | | | | | |
|---|---|---|---|---|---|
| Polymerizable | 41 | 41 | 41 | 41 | 41 |
| compound (for | | | | | |
| dispersion) | | | | | |
| Polymerizable | 11 | 11 | 11 | 11 | 11 |
| compound | | | | | |
| Photopolymerization | 3 | 3 | 3 | 3 | 3 |
| initiator | | | | | |
| Light diffusing agent | 4 | 4 | 4 | 4 | 4 |

### Preparation of Solvent-Based Curable Compositions

Based on the following respective components, curable compositions according to Examples 5 to 8 and Comparative Examples 6 to 10 were prepared.

### (A) Quantum Dot

(A-1) Green quantum dot surface-modified with the compound of Chemical Formula A-1 (Preparation Example 1)
(A-2) Green quantum dot surface-modified with the compound of Chemical Formula B-1 (Preparation Example 2)
(A-3) Green quantum dot surface-modified with the compound of Chemical Formula C-1 (Preparation Example 3)
(A-4) Green quantum dot surface-modified with the compound of Chemical Formula D-1 (Preparation Example 4)
(A-5) Green quantum dots without surface modification (Comparative Preparation Example 1)
(A-6) Green quantum dots surface-modified with the compound of Chemical Formula W (Comparative Preparation Example 2)
(A-7) Green quantum dots surface-modified with the compound of Chemical Formula X (Comparative Preparation Example 3)
(A-8) Green quantum dots surface-modified with the compound of Chemical Formula Y (Comparative Preparation Example 4)
(A-9) Green quantum dots surface-modified with the compound of Chemical Formula Z (Comparative Preparation Example 5)

### (B) Polymerizable Compound

Dipentaerythritol hexaacrylate (DPHA, Nippon Kayaku Co., Ltd.)

### (C) Photopolymerization Initiator

Oxime-based initiator (PBG-305, Tronyl)

### (D) Light Diffusing Agent

Titanium dioxide dispersion (rutile type TiO₂; D50 (180 nm), solid content 50 wt %, Iridos Co., Ltd.)

### (E) Binder Resin

TA-001 (Tacoma Corporation)

### (F) Solvent

(F-1) Cyclohexyl acetate (Sigma-Aldrich)
(F-2) Propylene glycol monomethylether acetate (PGMEA) (Sigma-Aldrich)

### Examples 5 to 8 and Comparative Examples 6 to 10

The following components were used to prepare each photosensitive resin composition of Examples 5 to 8 and Comparative Examples 6 to 10 having a composition shown in Tables 3 and 4 (unit: wt %).

A photopolymerization initiator was dissolved in a solvent (F-2) and then, sufficiently stirred for 2 hours at room temperature. Subsequently, a polymerizable compound, a binder resin, and a light diffusing agent were added thereto and then, sufficiently stirred for 15 minutes and stirred again for 1 hour at room temperature. On the other hand, a quantum dot and dispersant was added to a solvent (F-1) and then, stirred at room temperature for 30 minutes to prepare a quantum dot solution. Subsequently, the quantum dot solution was mixed with the other solution in which the photopolymerization initiator and the like were dissolved and then, stirred for 30 minutes at room temperature, and the products was three times filtered to remove impurities to prepare a solvent-type curable composition.

TABLE 3

| | | Example 5 | Example 6 | Example 7 | Example 8 |
|---|---|---|---|---|---|
| Quantum | (A-1) | 9 | — | — | — |
| dot | (A-2) | — | 9 | — | — |
| | (A-3) | — | — | 9 | — |
| | (A-4) | — | — | — | 9 |
| Polymerizable | | 7 | 7 | 7 | 7 |
| compound | | | | | |
| Photopolymerization | | 7 | 7 | 7 | 7 |
| initiator | | | | | |
| Light diffusing agent | | 2 | 2 | 2 | 2 |
| Binder resin | | 10 | 10 | 10 | 10 |
| Solvent | (F-1) | 30 | 30 | 30 | 30 |
| | (F-2) | 35 | 35 | 35 | 35 |

TABLE 4

| | | Comparative | Comparative | Comparative | Comparative | Comparative |
|---|---|---|---|---|---|---|
| | | Example 6 | Example 7 | Example 8 | Example 9 | Example 10 |
| Quantum | (A-5) | 9 | — | — | — | — |
| dot | (A-6) | — | 9 | — | — | — |
| | (A-7) | — | — | 9 | — | — |
| | (A-8) | — | — | — | 9 | — |
| | (A-9) | — | — | — | — | 9 |
| Polymerizable | | 7 | 7 | 7 | 7 | 7 |
| compound | | | | | | |
| Photopolymerization | | 7 | 7 | 7 | 7 | 7 |
| initiator | | | | | | |
| Light diffusing | | 2 | 2 | 2 | 2 | 2 |
| agent | | | | | | |
| Binder resin | | 10 | 10 | 10 | 10 | 10 |
| Solvent | (F-1) | 30 | 30 | 30 | 30 | 30 |
| | (F-2) | 35 | 35 | 35 | 35 | 35 |

### Evaluation: Evaluation of Light Resistance Reliability of Curable Compositions

The light resistance reliability of each of the curable compositions according to Examples 1 to 8 and Comparative Examples 1 to 10 was evaluated, and the results are shown in Table 5.

### Method for Evaluating Light Resistance Reliability

The prepared curable composition was manufactured into a 2 cm×2 cm single film specimen and then, measured with respect to light efficiency over time under a light source condition of blue 100,000 nit by using a blue LED planar light source.

The single film specimen was measured with respect to light efficiency and luminance over time by using an integrating sphere equipment (QE-2100, Otsuka Electronics Co., Ltd.) and an in-line luminance meter (M7000, McScience Inc.).

Based on 100% of an initial measurement, T90 (time taken until 100% of the initial light efficiency measurement drops to 90%) was compared and evaluated.

TABLE 5

| | T90 (hr) |
|---|---|
| Example 1 | 220 |
| Example 2 | 230 |
| Example 3 | 215 |
| Example 4 | 200 |
| Example 5 | 150 |
| Example 6 | 160 |
| Example 7 | 140 |
| Example 8 | 125 |
| Comparative Example 1 | <1 |
| Comparative Example 2 | 15 |
| Comparative Example 3 | 78 |
| Comparative Example 4 | 100 |
| Comparative Example 5 | 85 |
| Comparative Example 6 | <1 |
| Comparative Example 7 | 8 |
| Comparative Example 8 | 50 |
| Comparative Example 9 | 80 |
| Comparative Example 10 | 67 |

From Table 5, the curable composition according to some example embodiments can significantly improve light resistance reliability, regardless of whether a solvent is included. For example, the curable compositions according to Comparative Examples 5 and 10 have a large decrease in light efficiency due to a decrease in heat resistance, as they include quantum dots surface-modified with a surface-modifying material including an ester linkage, and thus the light resistance reliability is lowered.

While the subject matter of this disclosure has been described in connection with what is presently considered to be practical example embodiments, it is to be understood that the present disclosure is not limited to the disclosed embodiments, but, on the contrary, is intended to cover various suitable modifications and equivalent arrangements included within the spirit and scope of the appended claims, and equivalents thereof. Therefore, the aforementioned embodiments should be understood to be examples but not limiting the present disclosure in any way.

What is claimed is:

1. A curable composition, comprising:
(A) a quantum dot comprising a functional group represented by Chemical Formula 1; and
(B) a polymerizable compound: 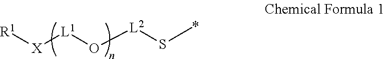
wherein, in Chemical Formula 1,
X is a sulfur atom or an oxygen atom,
R¹ is a monovalent functional group comprising a reactive group and a C3 to C20 cycloalkane ring,
L¹ and L² are each independently a substituted or unsubstituted C1 to C20 alkylene group, and
n is an integer between 2 and 10.

2. The curable composition as claimed in claim 1, wherein:
the reactive group comprises a carbon-carbon double bond, an epoxy group, or a combination thereof.

3. The curable composition as claimed in claim 1, wherein:
R¹ is represented by any one selected from Chemical Formulas R-1 to R-3: 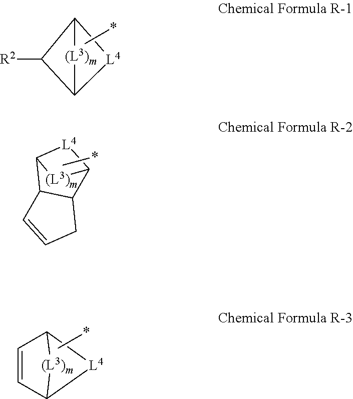
wherein, in Chemical Formulas R-1 to R-3,
R² is a substituted or unsubstituted vinyl group, a substituted or unsubstituted epoxy group, or a C1 to C20 alkyl group substituted with an epoxy group, and/or a vinyl group,
L³ and L⁴ are each independently a substituted or unsubstituted C1 to C10 alkylene group, and
m is an integer of 0 or 1.

4. The curable composition as claimed in claim 1, wherein:
the functional group represented by Chemical Formula 1 is represented by any one selected from Chemical Formula 1-1 to Chemical Formula 1-4: 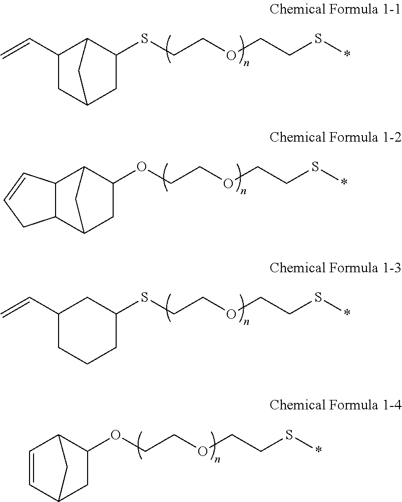
wherein, in Chemical Formula 1-1 to Chemical Formula 1-4,
n is an integer between 2 and 10.

5. The curable composition as claimed in claim 1, wherein:
the functional group represented by Chemical Formula 1 is derived from a compound represented by Chemical Formula 2: 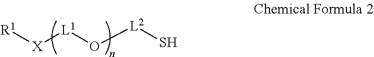
wherein, in Chemical Formula 2,
X is a sulfur atom or an oxygen atom,
R¹ is a monovalent functional group comprising a reactive group and a C3 to C20 cycloalkane ring,
L¹ and L² are each independently a substituted or unsubstituted C1 to C20 alkylene group, and
n is an integer between 2 and 10.

6. The curable composition as claimed in claim 1, wherein:
the curable composition is a solvent-free curable composition.

7. The curable composition as claimed in claim 6, wherein:
5 wt % to 60 wt % of the quantum dots; and
40 wt % to 95 wt % of the polymerizable compound
based on a total amount of the solvent-free curable composition.

8. The curable composition as claimed in claim 1, wherein:
the curable composition further comprises a polymerization initiator, a light diffusing agent, a polymerization inhibitor, or a combination thereof.

9. The curable composition as claimed in claim 8, wherein:
the light diffusing agent comprises barium sulfate, calcium carbonate, titanium dioxide, zirconia, or a combination thereof.

10. The curable composition as claimed in claim 1, wherein:
the curable composition further comprises malonic acid; 3-amino-1,2-propanediol; a silane coupling agent; a leveling agent; a fluorinated surfactant; or a combination thereof.

11. The curable composition as claimed in claim 1, wherein:
the quantum dot comprises a cadmium-free light emitting material.

12. The curable composition as claimed in claim 11, wherein:
the quantum dot has a core/shell structure of InP/ZnS or a core/first shell/second shell structure of InP/ZnSe/ZnS.

13. The curable composition as claimed in claim 1, wherein:
the quantum dot comprises a core comprising Ag, In, Ga, and S; and a shell including at least two selected from Ag, Ga, Zn, and S.

14. The curable composition as claimed in claim 1, wherein:
the curable composition further comprises a solvent.

15. The curable composition as claimed in claim 14, wherein:
the curable composition comprises:
1 wt % to 40 wt % of the quantum dot;
1 wt % to 20 wt % of the polymerizable compound; and
40 wt % to 80 wt % of the solvent
based on a total weight of the curable composition.

16. A cured layer produced using the curable composition as claimed in claim 1.

17. A display device comprising the cured layer as claimed in claim 16.
